(19) United States
(12) Patent Application Publication
(10) Pub. No.: US 2026/0194608 A1
(43) Pub. Date: Jul. 9, 2026

(54) A DEVICE AND A METHOD FOR CORRELATING MEDICAL IMAGING AND SAMPLING OF A BIOLOGICAL SPECIMEN

(71) Applicants: Aarhus Universitet, Aarhus C (DK); Region Midtjylland, Viborg (DK)

(72) Inventor: Jens Christian Hedemann Sørensen, Egå (DK)

(73) Assignees: Aarhus Universitet, Aarhus C (DK); Region Midtjylland, Viborg (DK)

(21) Appl. No.: 19/130,622

(22) PCT Filed: Nov. 24, 2023
(86) PCT No.: PCT/EP2023/083057

§ 371 Date: May 16, 2025

(30) Foreign Application Priority Data
Nov. 24, 2022 (EP) 22209398.1

(51) Int. Cl. G01R 33/30

(52) U.S. Cl. CPC G01R 33/30

(57) ABSTRACT

Please replace the abstract of the application as filed with the following replacement A device, a kit and a method are for image guided stereotaxic sampling and oriented sectioning of a biological specimen for correlating 3D medical imaging to spatial transcriptomics. A device for holding a biological specimen during medical imaging has a non-magnetic supporting base and at least two rows of non-magnetic elements, wherein the device is configured for sustaining the biological specimen on the non-magnetic supporting base between the at least two rows of non-magnetic elements such that the biological specimen can be sliced along the non-magnetic elements into slices of a predetermined thickness and orientation after medical imaging. A method of correlating medical imaging and sampling of a biological specimen is also disclosed.

### CROSS-REFERENCE TO RELATED APPLICATIONS

The present application is the National Phase entry of International Patent Application No. PCT/EP2023/083057, filed Nov. 24, 2023, which claims priority to European Patent Application No. 22209398.1, filed Nov. 24, 2022, the entire contents of both are hereby incorporated by reference into this application.

### TECHNICAL FIELD

The present disclosure relates to a device, a kit and a method for image guided sampling and oriented sectioning of a biological specimen for correlating 3D medical imaging to spatial transcriptomics.

### BACKGROUND

The recent development of molecular techniques and bioinformatic tools allows for studying the pattern of the spatially oriented gene expression on the level of a single cell. Such data can be used not only in research but also in clinical practice. However, combining spatial transcriptomic with the data obtained using the in-vivo imaging methods is not trivial, and standardized methods are sparse. For example, combining neuroimaging voxel space with spatially oriented gene expression data may help to describe the brain function, its plasticity, and pathology on the level of a single voxel and lead to a better understanding of the changes seen using various imaging methods.

Most of researchers' current understanding of brain function and dysfunction has its firm base in what is called the “anatomical substrate”, i.e. the anatomical, histological, and histochemical domains within the large knowledge envelope called “neuroscience”.

However, the structure of the human brain is immensely complex and comprises a multitude of cell types including more than 100 billion neurons, astrocytes, vascular cells, and immune cells that interact dynamically in both time and space. These cells communicate via direct contacts and via the exchange of vesicles or signal molecules that diffuse within the extracellular spaces-all governed by mechanisms that we are just starting to understand. We now know that even low-abundance cell populations can play essential roles in the pathology of many human diseases and that studying the tissue en bloc distorts the picture.

Moreover, the brain is a very dynamic anatomical organ. It rebuilds itself during both physiological processes like development, learning, or aging as well as in the course of various neurological or psychiatric diseases. Those changes are often manifested as the physiological and structural alterations on various scales, from the nanoscale (e.g. changes in the gene expression on the cellular level), microscale (such as changes in dendritic spine number/synapse number, cell number, or cell morphology), to the macroscale (e.g. the remodeling of the gray matter structure and white matter tracks).

The demand for integration of medical imaging and transcriptomic data is increasing, as researchers strive to localize gene expression in time and space. Attempts to correlate nanometer-scale gene expression with cellular, micrometer-scale to millimetre-scale medical imaging are ongoing and at the forefront of the efforts to translate omics data to physiologic function and disease phenotypes. Accordingly, there is a great need to establish methods that combine data across methods that operate at various scales of resolution.

The development of spatial RNA transcriptomics and proteomics has already led to numerous paradigm-shifting discoveries. At the same time, new bioinformatics tools that integrate high-dimensional data on different biomolecules across molecular profiling platforms have been implemented to address many of the most pressing questions in human medicine. These studies have left scientists with an astonishing recognition of cellular complexity. Each gene usually gives rise to a large number of transcripts by “alternative splicing” where the information is stitched together in different but often cell-specific manners.

### SUMMARY

Therefore, there is a need for the development of devices and/or methods that will allow for a correlation of medical imaging data, more specifically imaging phenotype, with gene expression patterns. Despite the advantages provided by the ability to perform such correlation, no versatile device or method allowing the correlation between medical imaging and biological specimen slices have been developed so far.

As disclosed here, however, a solution to this problem is provided by a device for holding a biological specimen during medical imaging, said device comprising a non-magnetic medical imaging compatible reference frame. The device is preferably configured for sustaining the biological specimen in fixed relation to the non-magnetic medical imaging compatible reference frame, such that at least one sample can be acquired from the biological specimen in fixed spatial relation with the non-magnetic medical imaging compatible reference frame after medical imaging. In the preferred embodiment the non-magnetic medical imaging compatible reference frame comprises a supporting base, preferably non-magnetic, and at least two rows of elements, preferably non-magnetic elements. In the preferred embodiment the device is configured for sustaining/holding the biological specimen in the non-magnetic medical imaging compatible reference frame, e.g. on the supporting base between the at least two rows of elements, such that the biological specimen can be sliced along the elements into one or more slices of a predetermined thickness and orientation. The real advantage is that this slicing can be performed after the medical imaging and that the predetermined thickness and orientation can be determined by the configuration of the rows of the elements, i.e. each slice is in fixed spatial relation with the non-magnetic medical imaging compatible reference frame.

Via the non-magnetic medical imaging compatible reference frame, a correlation, preferably a spatial correlation, can be made between medical imaging and at least one sample from the biological specimen, e.g. in the form of specimen slices. In particular because the medical imaging typically provides a spatial reference, e.g. a coordinate system, possibly including spatial coordinates of at least part of the biological specimen seen in the corresponding medical image(s). The non-magnetic medical imaging compatible reference frame of the presently disclosed device for holding the biological specimen, then provides the necessary correlation between the spatial reference/coordinate system/spatial coordinates of the biological specimen in the medical image and spatial coordinates of the biological specimen in the mould, which can further be correlated with spatial coordinates of at least one sample from the biological specimen created in accordance with the non-magnetic medical imaging compatible reference frame. E.g. by holding a biological specimen during medical imaging and further being able to slice the biological specimen into slices of a predetermined thickness and orientation, via the non-magnetic medical imaging compatible reference frame, spatial correlation is provided between medical imaging and at least one biological sample from the biological specimen, typically acquired after medical imaging.

Another aspect of the present disclosure relates to a kit for holding and/or sectioning a biological specimen comprising a device for holding a biological specimen during medical imaging, such as the one disclosed herein, a cutting unit, like a knife or string, for sectioning the biological specimen into slices and/or a material for arranging the biological specimen in the device, preferably a mouldable and/or non-ferromagnetic material.

The mouldable and/or non-ferromagnetic material can be generally described as a mould in the description.

The kit allows the slicing of the biological specimen held in the device disclosed herein, while the mouldable non-ferromagnetic material allows the arrangement of the biological specimen in the device, therefore holding the biological specimen in a given position during medical imaging, before possibly slicing it with the knife.

In one embodiment, the mouldable non-ferromagnetic material is an alginate embedding material or an alginate derived embedding material.

In another embodiment, the mouldable non-ferromagnetic material is compatible with magnetic resonance imaging. The mouldable non-ferromagnetic material may be configured to result in a low intensity magnetic resonance image with no visible distortion or noise and/or to deliver a null MRI signal. By resulting in a low intensity magnetic resonance image with no visible distortion or noise and/or to deliver a null MRI signal, the mouldable non-ferromagnetic material maintain the biological specimen in a given position within the device, thereby conserving the spatial correlation between medical imaging and the position of the biological specimen in the mould or more generally in the device, even though the device is moved or transported, which would cause the biological specimen to be displaced after acquiring medical images of the biological specimen.

At least one cavity may be formed in the non-ferromagnetic material. As the non-ferromagnetic material is typically invisible to the magnetic resonance, such a cavity can create a fiducial marker in magnetic resonance imaging.

The at least one cavity can be performed by a cavity tool. A cavity tool can be any tool that can be used to perform at least one cavity in the mouldable non-ferromagnetic material. Preferably, the cavity tool can be a biopsy tool as described herein.

The cavity tool can be arranged on the stereotaxic frame system as described and/or discussed herein. By arranging the cavity tool on the stereotaxic frame system as described or discussed herein, the at least one cavity performed in the mould can be localized in the stereotaxic space, thereby allowing a spatial correlation between medical imaging and the position of the biological specimen in the mould and/or the at least one cavity in the mould. Preferably, the cavity tool can be arranged on the sample collector unit.

The present disclosure further relates to a method of correlating medical imaging and sampling of a biological specimen. The method comprises the steps of providing a biological specimen, arranging the biological specimen in a mould for holding the biological specimen, acquiring at least one medical image of the biological specimen in the mould, said medical image(s) comprising a spatial reference, obtaining spatial coordinates of the biological specimen in the image(s) based on the spatial reference, correlating the spatial coordinates of the image(s) to spatial coordinates of the biological specimen in the mould; and extracting one or more sample(s) of the biological specimen in the mould; thereby obtaining one or more samples of the biological specimen correlated to the medical image(s) of said biological specimen.

The method thus allows to correlate the medical image, such as the digital voxels of a medical resonance imaging (MRI) image, with the 3D coordinates of the biological specimen. The method may comprise a device for holding the mould holding the biological specimen, which further comprises a stereotaxic unit defining the biological specimen in stereotaxic space. The method may also further comprise the processing of the spatially-resolved biological specimen, such as by sectioning, for instance cryo-sectioning, or for example by biopsy, to perform histological and/or spatial transcriptomics analyses and/or biochemical and/or mass spectometric and/or chromatographic analyses on the sample(s) and/or sub-sample(s). Altogether, the method enables the precise correlation of the spatial transcriptomics and/or molecular data of a biological sample to its stereotaxic anatomical localization and structural information obtained by medical imaging, such as MRI. In combining MRI, down to e.g. detection of tissue microstructure, with spatial transcriptomics, down e.g. to single cell gene expression, the presently disclosed approach will allow for a better understanding of e.g. pathological processes in a well-defined tissue space on various scales.

### BRIEF DESCRIPTION OF THE DRAWINGS

In the following embodiment and examples will be described in greater detail with reference to the accompanying drawings:

FIG. 1A-D show embodiments and section views of a device for holding a biological specimen during medical imaging as disclosed herein, wherein the non-magnetic elements are rods, and wherein the base surface is minimized;

FIG. 2A-D show embodiments and section views of a device for holding a biological specimen during medical imaging as disclosed herein, wherein the non-magnetic elements are rods, and wherein the base surface is extended;

FIG. 3 shows an embodiment of a device for holding a biological specimen during medical imaging as disclosed herein, wherein a stereotaxic unit is arranged on the device;

FIG. 4 shows an embodiment of the disclosed kit, comprising a device for holding a biological specimen during medical imaging and a knife as disclosed herein;

FIG. 5 shows an embodiment of the steps of the method of correlating medical imaging and sampling of a biological specimen disclosed herein, from providing a biological specimen in a mould to obtaining spatial coordinates of the biological specimen in the image(s) based on the spatial reference (the example of X-Y-Z coordinates in the voxel space in MRI is presented for example in the lower panels);

FIG. 6 shows a pilot test of the prototype of the MRI compatible slicer (HistOtech slicer), allowing for correlation of the voxel space with histological sections or biopsies. HistOtech slicer (A), Preparation of the alginate polymer (HistOmer) for embedding the biological sample (B), Embedding the minipig brain in the polymer inside the HistOtech slicer (C), HistOtech slicer inside a 3T MRI scanner (D, E), MRI Scan of the brain, note the lack of signal from the HistOtech slicer (F), Coronal view of the brain with visible biopsy site (G), Brain slabbing/slicing (H), Brain slabs/slices (I), Brain slab/slice with visible biopsy hole marked with arrows (J), Brain slab/slice and obtained biopsy marked with arrows (left) and spatial transcriptomics analysis workflow, GeoMX® platform (right), ROI: Region Of Interest. (K); and

FIG. 7 shows a schematic overview of an example of spatial transcriptomics technology, along with the downstream analysis, the barcoded microarrays containing printed spots of reverse transcription (RT)-primers with unique barcode sequences, wherein each spot has a diameter of 100 microns, thus corresponding to a tissue domain, and wherein the center-to-center distance is 200 microns. Samples, and/or sub-samples of the biological specimen spatially correlated to the at least one medical image(s) of said biological specimen obtained by the methods of the present invention may be used for spatial transcriptomics approaches.

### DETAILED DESCRIPTION

The present disclosure relates to a device for holding a biological specimen during medical imaging, said device comprising a non-magnetic medical imaging compatible reference frame, wherein the device may be configured for sustaining the biological specimen in fixed relation to the reference frame, such that at least one sample can be acquired from the biological specimen in fixed spatial relation with the reference frame after medical imaging.

The non-magnetic medical imaging compatible reference frame may comprise a non-magnetic supporting base for holding or sustaining the biological specimen. The reference frame can further comprise at least two rows of non-magnetic elements, and wherein the reference frame may be configured for sustaining the biological specimen on the non-magnetic supporting base between the at least two rows of non-magnetic elements such that the biological specimen can be sliced along the non-magnetic elements into slices of a predetermined thickness and orientation after medical imaging.

The fixed spatial relation may be determined by an original placement of the biological specimen within the reference frame. The original placement may be determined by an orientation and/or a position of the biological specimen within the reference frame.

By having the reference frame comprising the at least two rows of non-magnetic elements, a spatial correlation between the slices of the biological specimen and the orientation and/or the position of the biological specimen within the reference frame can be obtained.

The medical imaging may be magnetic resonance imaging. Magnetic resonance imaging is a medical imaging technique used in radiology to form pictures of biological specimen, such as anatomy and physiological processes of a body. Magnetic resonance scanners use strong magnetic fields, magnetic field gradients, and radio waves to generate images of the organs in the body. The medical imaging can be other medical imaging techniques such as X-rays, computed tomography (CT) scans, ultrasound or nuclear medicine imaging, including positron-emission tomography (PET). Magnetic resonance imaging may offer a better precision of the medical imaging compared to the other medical imaging techniques.

The non-magnetic supporting base may have a surface that can either be extendable and/or retractable. The non-magnetic supporting base can be configured such as the surface of the base can be adapted to any biological specimen sizes. The non-magnetic supporting base can be made with a non-magnetic material such as it may be compatible with magnetic resonance imaging. The non-magnetic material can be plastic or Plexiglas, which would advantageously limit the total weight of the device comprising the non-magnetic supporting base, but any other non-magnetic material can also be used.

The non-magnetic supporting base can be plane. This can be beneficial in order to comfortably place and hold the biological specimen in the device. The non-magnetic supporting base may also have different shapes, which would preferably suit the biological specimen shape that needs to be hold in the device comprising the non-magnetic supporting base. The surface of the non-magnetic supporting base may have an area between 5 cm² and 1000 cm² such that any organs or biological specimen can be hold and placed on it. The surface of the non-magnetic supporting base may be maximized by the size of the aperture of a magnetic resonance imaging. Traditional MRI scanners may have a 60 cm bore but larger bore such as 70 cm may exist, but this may require a higher strength magnetic field.

The device for holding a biological specimen may comprise non-magnetic elements that can be separated with a spacing distance. The spacing distance may define the predetermined thickness when cutting the biological specimen into slices. The non-magnetic elements may have different geometries and sizes, but they may be preferably adapted to the biological specimen that can be sliced.

The spacing distance separating the non-magnetic elements may be between 0.2 mm and 4 mm, preferably between 0.4 mm and 2 mm, even more preferably less than 1 mm. The spacing distance separating the non-magnetic elements can be used as a guide for a slicing tool. The cutting part of slicing tool can slice the biological specimen if it is inserted in between at least two non-magnetic elements. A smaller distance may define a better and cleaner cut of the slices than a longer distance between the non-magnetic elements. Indeed, a longer distance may cause the cutting part of the slicing tool to be slightly bended between two non-magnetic elements, depending on the width of the cutting part of the slicing tool. A smaller distance may require more non-magnetic elements than a longer distance between the non-magnetic elements.

At least two rows of non-magnetic elements may be arranged at a plurality of boundaries of the non-magnetic supporting base. The at least two rows of the non-magnetic elements may be preferably arranged in two opposite sides of the non-magnetic supporting base. The plurality of boundaries may also be adjacent boundaries of the non-magnetic supporting base.

The length of the non-magnetic elements may be between 10 and 400 mm, preferably between 20 and 200 mm.

The non-magnetic elements can be arranged such as at least one non-magnetic element may be visually different than the others. The visual difference can be a size difference, a colour difference or a texture difference. The visual difference may also be a length difference where one or more of the non-magnetic elements have a primary length while the remaining non-magnetic elements have a secondary length. The primary and secondary length can be measured from the non-magnetic supporting base of the device to the top of the non-magnetic elements.

The non-magnetic elements having the primary length may be arranged between every two non-magnetic elements and ten non-magnetic elements in each one of the at least two rows of non-magnetic elements, preferably between every five non-magnetic elements.

The ratio in length between the primary length and the secondary length may be between 1 and 1.5, preferably between 1.1 and 1.2.

The non-magnetic elements can be non-magnetic rods. A non-magnetic rod may be defined as a long straight piece made of non-magnetic material. The non-magnetic rod can have a rectangular, square, cylindrical, ovoid or rounded shape. The non-magnetic may be preferably cylinders, more preferably right circular cylinders. A right circular cylinder is a three-dimensional solid shape that consists of two parallel bases linked by a closed circular disk in shape. The right circular cylinders may comprise a primary axis, which is defined as being the axis crossing the two centres of the two ends of the cylinders. The right circular cylinders may have a diameter between 1 mm and 1 cm, preferably between 1 mm and 20 mm, even more preferably around 4 mm in diameter. The diameter of the right circular cylinders defines the minimum thickness of slices. Indeed, when cutting slices of the biological specimen, a cutting tool, such as a blade, may be inserted and slit between two non-magnetic elements in order to make one cut, and a resulting minimum slice thickness may be achieved by making a second cut between the two next non-magnetic elements.

The primary axis of the non-magnetic rods may be perpendicular to the flat surface of the non-magnetic supporting base. The primary axis can be substantially perpendicular to the flat surface of the non-magnetic supporting base. The primary axis may be arranged on the flat surface of the non-magnetic supporting base, wherein the primary axis and the flat surface of the non-magnetic supporting base form an angle that can be comprised between 0 and 180°, preferably between 8° and 100°.

The at least two rows of the non-magnetic rods are straight. The non-magnetic rods can be arranged in rows, which means that the intersections of the primary axis of each of the non-magnetic rods with the non-magnetic supporting base can be connected with a straight line. The at least two rows of non-magnetic rods are parallel. Preferably, two rows of non-magnetic rods can be arranged in parallel on the non-magnetic supporting base, such as the cutting part of the slicing tool can be guided along the non-magnetic rods in order to cut slices of the biological specimen. More preferably, the at least two rows of non-magnetic rods can be arranged on the boundary of the non-magnetic supporting base, in order to benefit from a maximum of the area of the non-magnetic supporting base to place the biological specimen in between the at least two rows of non-magnetic rods.

The non-magnetic rods can be preferably made with carbon. Carbon rods are made of high purity carbon. This is often used as an electrode where heat resistance or resistance to chemicals is needed. Carbon rods are preferably made of a specific type of carbon known as graphite. This type of carbon is highly resistant to heat and chemicals. Carbon has the high advantage to be non-magnetic, since it is not even magnetic in the atomic state since the spin and the angular momentum of its six electrons cancel to produce a net magnetic moment of zero. It may also have the advantage to be extremely robust, compared to other materials, especially when it is used to make long rods with a tiny diameter. Plastic (e.g. Peek) or Plexiglas can also be materials of interest to make the non-magnetic rods.

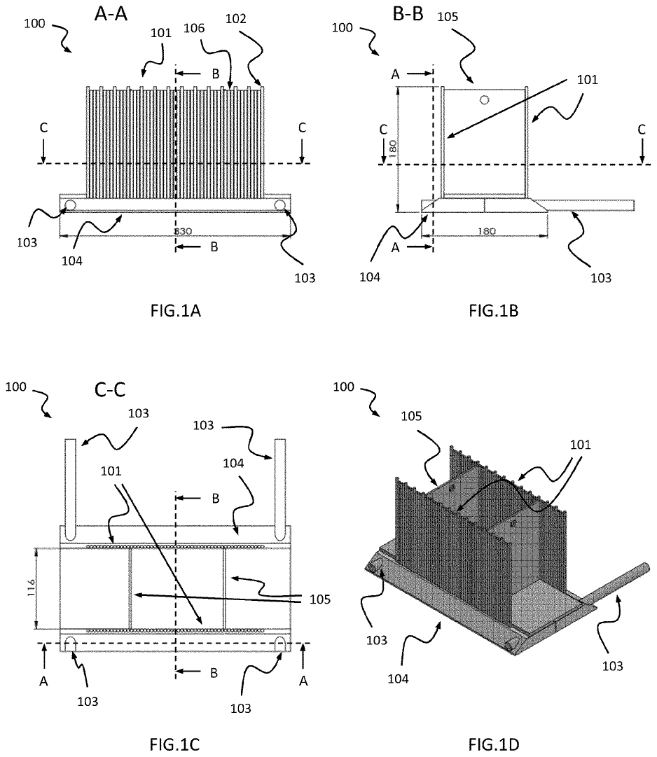

FIG. 1A-D show embodiments and section views of a device for holding a biological specimen during medical imaging 100 as disclosed herein, wherein the non-magnetic elements are rods 101, and wherein the base surface is minimized. FIG. 1D shows an embodiment of a device for holding a biological specimen during medical imaging 100 as disclosed herein. The surface of the supporting base 104 can be extended or reduced thanks to a mechanism comprising two tubes 103, preferably located on each extremity of the supporting base, on which the supporting base can be slid. In this configuration as shown in FIG. 1D, the surface of the supporting base 104 is minimized. Two rows of non-magnetic rods 101 are arranged on two opposite sides of the device, and are arranged vertically on the supporting base 104. As described herein, the non-magnetic rods have two different lengths, such as a primary length 102 and a secondary length 106. On the device shown in FIG. 1D, one every five rods are higher than the rest of the rods. Preferably, one every two rods, more preferably one every three rods, even more preferably one every four rods may be higher than the rest of the rods. This gives a visual reference for the user in order to insert the slicing device between the correct rods. Two movable walls 105 are disposed on each side of the device. The two movable walls are used to delimit an area where the biological specimen is hold. Moreover, the two movable walls 105 may form a barrier if any mouldable non-ferromagnetic material is disposed in the area where the biological specimen is hold. FIG. 1A shows a side section view (A-A) of an embodiment of a device for holding a biological specimen during medical imaging as disclosed herein. FIG. 1B shows a second side section view (B-B) of an embodiment of a device for holding a biological specimen during medical imaging as disclosed herein. FIG. 1C shows a top section view (C-C) of an embodiment of a device for holding a biological specimen during medical imaging as disclosed herein.

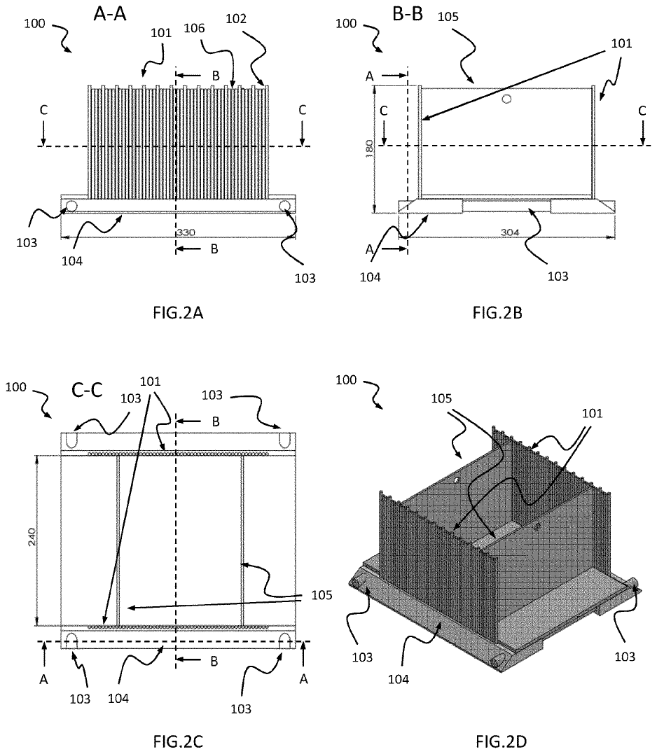

FIG. 2A-D show embodiments and section views of a device for holding a biological specimen during medical imaging 100 as disclosed herein, wherein the non-magnetic elements are rods 101, and wherein the base surface is extended. FIG. 2D shows an embodiment of a device for holding a biological specimen during medical imaging 100 as disclosed herein. The surface of the supporting base 104 can be extended or reduced thanks to a mechanism comprising two tubes 103, preferably located on each extremity of the supporting base, on which the supporting base can be slid. In this configuration as shown in FIG. 2D, the surface of the supporting base is extended. Two rows of non-magnetic rods 101 are arranged on two opposite sides of the device, and are perpendicular with the supporting base 104. As described herein, the non-magnetic rods have two different lengths, such as a primary length 102 and a secondary length 106. On the device shown in FIG. 2D, one every five rods are higher than the rest of the rods. Preferably, one every two rods, more preferably one every three rods, even more preferably one every four rods may be higher than the rest of the rods. This gives a visual reference for the user in order to insert the slicing device between the correct rods. Two movable walls 105 are disposed on each side of the device. The two movable walls 105 are used to delimit an area where the biological specimen is hold. Moreover, the two movable walls 105 may form a barrier if any mouldable non-ferromagnetic material is disposed in the area where the biological specimen is hold. FIG. 2A shows a side section view (A-A) of an embodiment of a device for holding a biological specimen during medical imaging as disclosed herein. FIG. 2B shows a second side section view (B-B) of an embodiment of a device for holding a biological specimen during medical imaging as disclosed herein. FIG. 2C shows a top section view (C-C) of an embodiment of a device for holding a biological specimen during medical imaging as disclosed herein.

The biological specimen as previously defined can be a block of tissue. The term “block” is used herein to refer to any block or chunk of any shape. Herein “tissue” is a cellular organizational level intermediate between cells and a complete organism. A block of tissue can be defined as a part of an organism of a large number of cells, not necessarily identical, but having a similar structure and/or function. The block of tissue may preferably be one or more organs or at least a part of an organ. The organ can be either a human organ or an organ coming from a non-human animal, which is any living thing that is not a plant or a human. The biological specimen may be obtained from a living donor or post-mortem. The biological specimen may also be obtained from plants, such as vegetables or fruits, for example the biological specimen may be a whole plant, vegetable or fruit, or parts thereof.

The device for holding a biological specimen may further comprise a stereotaxic unit configured for being arranged in fixed spatial relation to the non-magnetic medical imaging compatible reference frame for defining the biological specimen in stereotaxic space before, during and/or after medical imaging.

Stereotaxic space may refer to stereotaxic surgery, also called stereotactic surgery or stereotaxy, which is a three-dimensional surgical technique. Stereotactic surgery is a minimally invasive form of surgical intervention which makes use of a three-dimensional coordinates system to locate small targets inside an organ, preferably a brain, and to perform some action on the small targets. The stereotactic surgery works on the basis of three main components:
A stereotactic planning system, that may include an atlas,
A stereotactic device or apparatus, and
A stereotactic localization and placement procedure.

The stereotactic atlas is a series of cross sections of anatomical structure, depicted in reference to a two-coordinate frame. Thus, each organ structure can be easily assigned a range of three coordinate numbers, which will be used for positioning the stereotactic device. In most atlases, the three dimensions are latero-lateral (x), dorso-ventral (y) and rostro-caudal (z).

There can be multiple different type of stereotaxy, among them is the frame-based stereotaxy and the frameless stereotaxy. Both may use elements providing a spatial reference on medical images, such as fiducial markers. Fiducial markers allow the navigation to be based upon targeting relative to known spatial reference points. A fiducial marker may be defined as a point of reference that can be visualized on imaging and identified. The accuracy of targeting may be influenced by the number of fiducials around a target zone and the constancy of fiducials relative to the target. Other systems as described further below may also be used as spatial reference(s), including on medical images.

The frame-based stereotaxy can rely on fiducials, that can be made with bars built into cage or box that site on frame during imaging. The frameless stereotaxy can rely on fiducials that may be reference markers, such as stickers or bone screws, which may be fixed directly to an object, like for example a patient or an animal to be scanned, prior to imaging. The frameless stereotaxy can however also rely on fixed anatomical structures such as surface anatomy, skeleton or cranium.

The stereotaxic unit may be configured for detachable attachment on the non-magnetic medical imaging compatible reference frame such that a correlation between spatial coordinates or spatial stereotaxic coordinates of the biological specimen in medical imaging and stereotaxically-extracted samples, such as slices of the biological specimen, can be obtained. This may be relevant if the stereotaxic unit can be composed of non-magnetic and magnetic elements, which could not be compatible with a MRI scanning if the magnetic elements were not detachable from the unit. The stereotaxic unit may be a non-magnetic unit and in that specific case, the stereotaxic unit can be fixed to the non-magnetic medical imaging compatible reference frame or the device as defined herein prior to, during, and after imaging.

The stereotaxic unit can be arranged on the non-magnetic medical imaging compatible reference frame such that the stereotaxic space definition can be aligned and/or correlated with the coordinate system defined by the non-magnetic medical imaging compatible reference frame. The coordinate system can also be defined by the supporting base and the rows of non-magnetic elements.

The stereotaxic unit may be compatible with magnetic resonance imaging, which would avoid a user detaching some elements of the stereotaxic unit or even the stereotaxic unit in its entirety from the device during MRI scanning, or any other types of scanning as cited before. Indeed, some materials, even magnetic, can cause some undesirable or unwanted noise in the medical image obtained from a CT or PET scan.

In one embodiment, the stereotaxic unit comprises a localization device. A localization device as described herein can be any device allowing a localization of the biological specimen within the device for holding a biological specimen during medical imaging. Preferably, the localization device may be non-magnetic, so that the device can be compatible with magnetic resonance imaging.

In a preferred embodiment, the stereotaxic unit is a stereotaxic localizer box.

In another embodiment, the localization device is a N-localizer. A N-localizer may enable guidance of stereotactic surgery or radiosurgery using tomographic images. The tomographic images may be obtained via CT, MRI or positron emission tomography (PET). The N-localizer can comprise a diagonal rod that spans two vertical rods to form an N-shape and can permit calculation of the point where a tomographic image plane intersects the diagonal rod. By providing a N-localizer to the device for holding a biological specimen during medical imaging, a calculation of three points can be performed, where a tomographic image plane intersects two vertical rods and one diagonal rod. The intersection of the tomographic image plane with the N-localizer may create two fiducial circles and one fiducial ellipse. The relative spacing between the ellipse and the two circles may vary with the height at which the tomographic image plane intersects the diagonal rod, thereby allowing a correlation between the height where the tomographic image is located and the position of the biological specimen. Preferably, the relative spacing between the ellipse and the two circles may vary with the height at which the tomographic image plane intersects the diagonal rod, thereby determining the spatial orientation of the tomographic image plane relative to the non-magnetic imaging compatible reference frame.

The localization device may be a plurality of N-localizers. By having a plurality of N-localizers, a tomographic image plan orientation relative to the device for holding a biological specimen can be determined. Preferably, attaching three N-localizers to a stereotactic instrument can allow calculation of three points where a tomographic image plane intersects three diagonal rods. These points can determine the spatial orientation of the tomographic image plane relative to the device for holding a biological specimen.

The stereotaxic unit can be a stereotaxic frame system, preferably an arc-quadrant system. There can be multiple types of stereotaxic frame systems that can be arranged on the device. A list of some other stereotaxic frame options as well as their characteristics and features are described below:
Simple Orthogonal system: The probe is directed perpendicular to a square base unit fixed to an object, like for example a patient or an animal.
Stereotaxic unit akin that a person skilled in the art would define as a “Burr Hole Mounted System”: This provides a limited range of possible target points with a fixed entry point. The Burr Hole Mounted System provides two angular degrees of freedom and a depth adjustment.
Arc-Quadrant Systems: Probes are directed perpendicular to the tangent of an arc, which can rotate about the vertical axis, and a quadrant, which can rotate about the horizontal axis. The probe, directed to a depth equal to the radius of the sphere defined by the arc-quadrant, will always arrive at the center or focal point of that sphere.
Arc-Phantom Systems: An aiming bow attaches to a head ring, which in neurosurgery is fixed to a patient's skull, and can be transferred to a similar ring that contains a simulated target. In the case of the stereotaxic unit for sampling of a biological specimen as described herein, the ring can be fixated to the stereotaxic unit. In this system, the phantom target is moved on the simulator to 3D coordinates. After adjusting the probe holder on the aiming bow so that the probe touches the desired target on the phantom, the transferable aiming bow is moved from the phantom base ring to the base ring on the stereotaxic unit.

The stereotaxic unit may comprise a sample collector unit configured for acquiring at least one secondary sample of the biological specimen.

In one embodiment, the sample collector unit is movable along an arc defined by the stereotaxic unit. The arc can be substantially circular. The arc may allow the displacement of the sample collector unit on the stereotaxic unit. The sample collector unit may comprise a fixation system that may allow the sample collector unit to be movable along the arc defined by the stereotaxic unit. Preferably, the fixation system can comprise a locking system allowing the sample collector unit to be fixed in one location along the arc of the stereotaxic unit.

The arc defined by the stereotaxic unit may be rotated along a stereotaxic unit axis, where the stereotaxic unit axis is preferably arranged in the coronal or frontal plane, the horizontal, axial or transverse plane or the sagittal, longitudinal plane of the device. By rotating the arc along the stereotaxic unit axis defined by the stereotaxic unit, the sample collector unit can be arranged at any location around the device, thereby allowing the sample collector unit to acquire at least one secondary sample of the biological specimen in any desired locations.

The sample collector unit may be configured for performing an incisional biopsy or core biopsy. The sample collector unit may be attached to the stereotaxic unit, such as the sample collector unit may be moved on the stereotaxic unit, while preserving a spatial correlation with the stereotaxic unit, thereby preserving a spatial correlation with the device for holding a biological specimen.

The sample collector unit can be selected from a group of: needle, biopsy needle, hollow needle, scalpels, scissors, forceps, curette, punch. These sample collector unit may be configured for performing a biopsy of the biological specimen.

The sample collector unit may be arranged on the stereotaxic frame system. The at least one secondary sample can be comprised within the biological specimen. The at least one secondary sample may be substantially smaller than the at least one sample.

The at least one secondary sample can be a biopsy specimen, biopsy sample or a voxel of the biological specimen. A biopsy specimen, biopsy sample or a voxel, corresponding to an imaging of one or more imaging voxels of the biological specimen may be defined as a sample of the biological specimen, which may preferably not be a slice of the biological specimen, wherein the slice is an entire coronal, sagittal or transverse slice of the biological specimen. By performing an incisional biopsy or core biopsy of the biological specimen, thereby collecting the at least one secondary sample, the biological specimen may be partly preserved in its entirety. Preferably, the biological specimen may not be cut in two distinct biological specimens by cutting a slice as described herein, but rather be preserved as a biological specimen with a biopsy sample, a biopsy specimen or a voxel collection of the biological specimen.

The stereotaxic unit may comprise a device providing a spatial reference on medical images, such as a device enabling image-guidance of neurosurgery or radiosurgery by medical imaging, such as by MRI. Said device may for example be a N-localizer or N-bar. The stereotaxic unit may thus be a combination of a stereotaxic frame system and a device enabling image-guidance of neurosurgery or radiosurgery by medical imaging such as a N-localizer or N-bar. The frame-based stereotaxy can be performed with fiducials, for example, for providing spatial reference on medical images, such as bars built into cage or box that sits on frame during medical imaging. The N-localizer for frame-based stereotaxy may comprise three bars, such that the three bars are arranged to form a shape which looks like the letter N or Z. The intersection of the medical imaging with the N-localizer creates two fiducial circles and one fiducial ellipse. The relative spacing between the ellipse and the two circles varies according to the height at which the medical imaging plane intersects the diagonal bar. By measuring this spacing, the calculation of the point where the medical imaging intersects the diagonal bar or rod can be performed. Such systems, for instance, provide spatial references in medical images.

In one embodiment, the device comprises a plurality of movable walls. The movable walls can be used to set vertical boundaries on the boundary of the non-magnetic supporting base of the device. The movable walls are called movable because they can be mounted/unmounted from the device, depending on the needs of a user or an application. The movable walls may be used to create a barrier if a solution is used to arrange the biological specimen. By having movable walls arranged on the device, the solution can then accumulate in the device and cannot spread out from the device.

The plurality of movable walls can be preferably vertically arranged at a plurality of outer boundaries of the device. More preferably, the movable walls can be arranged on the outer of the at least two rows of non-magnetic elements.

The plurality of movable walls can be preferably made with non-magnetic materials. Preferably, the plurality of movable walls are made with plastic, such as Plexiglas. This may be a benefit to keep the weight of the device low, while having a relatively robust material, depending on the thickness of the plastic.

The non-magnetic supporting base can be in plastic, such as Peek or Plexiglas. Preferably, the non-magnetic base as well as the movable walls may be in a material that may not introduce noise and/or distortion in any types of medical imaging.

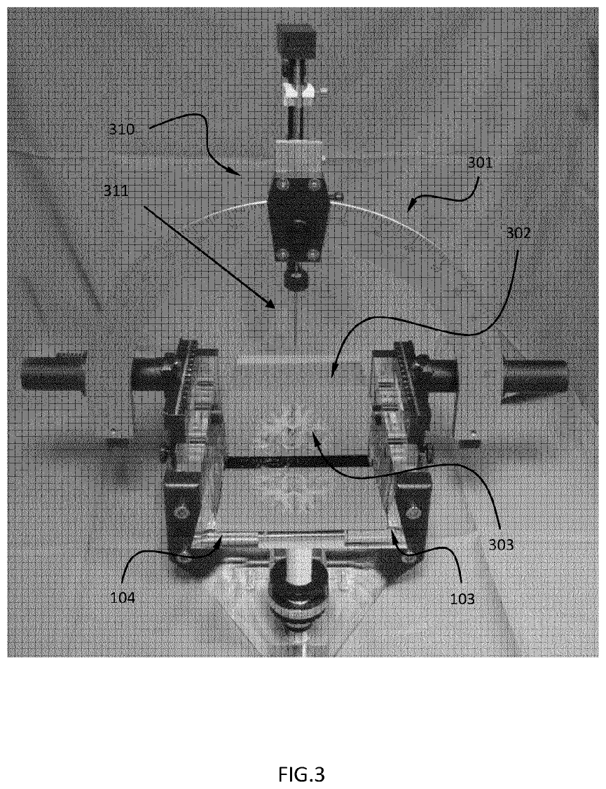

FIG. 3 shows an embodiment of a device for holding a biological specimen during medical imaging as disclosed herein, wherein a stereotaxic unit is arranged on the device. The device for holding a biological specimen during medical imaging further comprises a biological specimen 303, namely a brain, which is arranged in a mouldable material 302 and held in the device for holding a biological specimen. A stereotaxic unit 301 is attached to the device. As described herein, the stereotaxic unit may be MRI compatible with N-localizers attached such that it may not be needed to detach the stereotaxic unit from the device for holding a biological specimen, therefore having a fixed stereotaxic unit with the device for holding a biological specimen during imaging and localizing stereotaxic spatial coordinates for tissue sampling by for example a stereotaxic arc quadrant system as it can be seen on FIG. 3. In this specific embodiment as illustrated on FIG. 3, the stereotaxic unit further comprises a sample collector unit 310. The sample collector unit is arranged on the stereotaxic unit. The sample collector unit is configured for performing a biopsy on the biological specimen. In this specific embodiment, the sample collector unit is a needle 311. By having a sample collector unit on the stereotaxic unit, a specific sampling of at least one secondary sample of the biological specimen can be performed. This would allow the user of the device to specifically sample at least one secondary sample of the biological specimen, such as by performing a biopsy with the sample collector unit, thereby avoiding cutting slices in the biological specimen. As discussed herein, the stereotaxic unit provides a stereotaxic space reference. By having a sample collector unit arranged on the stereotaxic unit, thereby providing a stereotaxic space reference to the sample collector unit, a stereotaxic biopsy in X-Y-Z voxel coordinate can be performed. An arc is defined by the stereotaxic unit, on which the sample collector unit is arranged. The arc can be substantially round, spherical, circular, rounded, curvilinear, ovoid, globular, bulging, rotund, swell, or any combinations thereof. The arc can be a smooth curve, wherein the smooth curve is a curve which is a smooth function. In particular, a smooth curve is a continuous map from a one-dimensional space to an n-dimensional space which on its domain has continuous derivatives up to a desired order. The arc may preferably have a single concavity, wherein the single concavity is concave. The arc can be rotated around a stereotaxic unit axis. In FIG. 3, the stereotaxic unit axis is located at the intersection of the horizontal, transverse plane and the coronal or frontal plane. The stereotaxic unit axis could also be located at the intersection of the horizontal, transverse plane and the median plane. By rotating the arc around a stereotaxic unit axis, the sample collector unit can arrange the biopsy tool to any location of interest, such that the at least one secondary sample can be sampled within the biological specimen at the area of interest.

As it is shown in FIG. 3, the surface of the supporting base 104 of the device is adjusted thanks to mechanism comprising two tubes 103 to extend the surface of the supporting base 104, such that the biological specimen can be placed and hold in the device for holding a biological specimen 100.

FIG. 5 shows a biological specimen, more specifically a brain, which is embedded in a mould in the device for holding a biological specimen during medical imaging as described herein. A stereotaxic localizer box is arranged around the device for holding a biological specimen during medical imaging. By arranging a stereotaxic localizer box around the device for holding a biological specimen, a spatial correlation can be efficiently made between the medical imaging and the biological specimen by providing fiducial markers and/or localizers, such as N-localizers. The stereotaxic localizer box can be compatible with medical radio imaging, especially with magnetic resonance imaging. The device with the stereotaxic localizer box comprising the N-localizers can then be arranged in a MRI scanner for processing medical imaging of the biological specimen. A spatial correlation between the images obtained from the magnetic resonance imaging scan and the biological specimen in the mould can then be obtained based on the N-localizers comprised in the stereotaxic localizer box, which defines a stereotaxic X-Y-Z voxel space.

In another aspect, a kit for holding and/or sectioning a biological specimen is disclosed. The kit may comprise:
a device for holding a biological specimen during medical imaging as described herein;
a knife for sectioning the biological specimen into slices; and/or
a mould for arranging the biological specimen in the device.

The knife may comprise a blade or a cutting part made in titanium. The blade or the cutting part may also be in steel, other metal, carbon, or hard polymer. The blade or the cutting part may be preferably made with a material such as the slicing of the biological specimen may be sharp.

The blade may have a thickness between 0.1 and 1 mm, preferably between 0.1 and 0.9 mm. It is preferred that the thickness of the blade corresponds to the space between the non-magnetic elements. The blade may have a length between 10 and 50 cm, preferably between 30 and 50 cm. Preferably, the blade may have a length such as the blade can cut at least one slice of the biological specimen with only one slicing/cut.

The mould may preferably be a mouldable non-ferromagnetic material. The mouldable non-ferromagnetic material can be removed without damaging the biological specimen. The mouldable non-ferromagnetic material is an alginate embedding material, which can preferably be non-toxic and does not stick to- or influence the surrounded tissue. The alginate embedding material may be an alginate derived embedded material. The alginate embedding material polymerizes in one to ten minutes, preferably in two to five minutes. The alginate embedding material may be developed for low MRI signals.

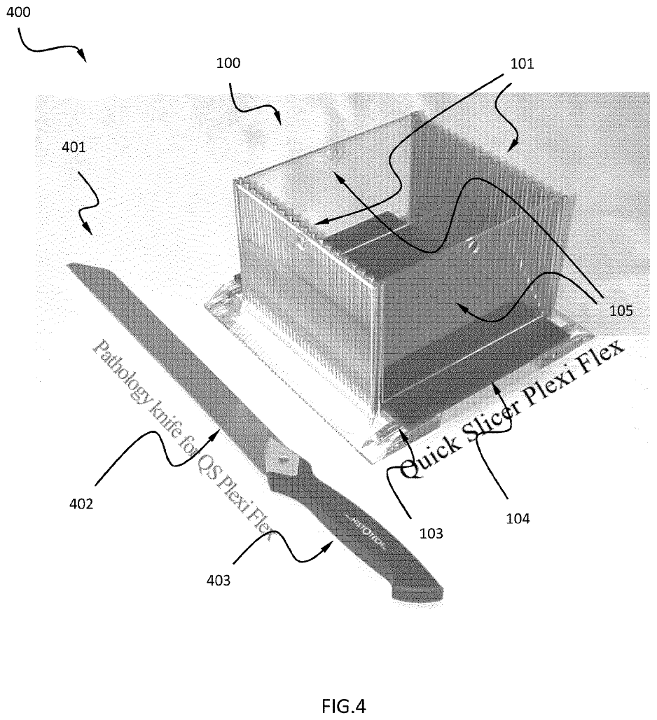

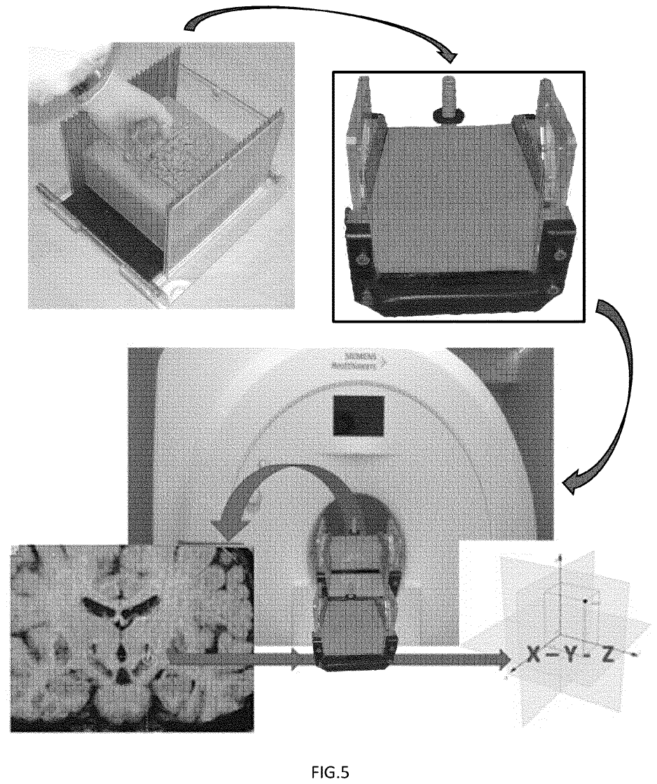

FIG. 4 shows an embodiment of the disclosed kit 400, comprising a device for holding a biological specimen during medical imaging 100 and a knife 401 as disclosed herein. The device for holding a biological specimen during medical imaging 100 comprises a supporting base, which can be extended by sliding the supporting base 104 along a mechanism comprising two tubes 103. It comprises two rows of non-magnetic rods 101, which are arranged perpendicular to the supporting base 104, on two opposite extremities of the device. The knife comprises a blade 402 and a handle 403 suitable for holding the knife while slicing the biological specimen hold in the device 100. The blade 402 may be long enough so that the blade 402 can be included between two rows of the two rows of non-magnetic rods 101. The movable walls are disposed close to each extremity of the two rows of non-magnetic rods, but may alternatively be disposed in between any of the rods comprised in the two rows, such that it fits closer to the size of the biological specimen hold into the device. By moving the movable walls closer to each other, this also minimize the quantity of non-ferromagnetic material to be filed inside the device.

### Correlation of Medical Imaging and Sampling of a Biological Specimen.

Another aspect of the present invention relates to a method of correlating medical imaging and sampling of a biological specimen, comprising the steps of:
providing a biological specimen;
arranging the biological specimen in a mould for holding the biological specimen;
acquiring at least one medical image of the biological specimen in the mould, said medical image(s) comprising a spatial reference;
obtaining spatial coordinates of the biological specimen in the image(s) based on the spatial reference;
correlating the spatial coordinates of the image(s) to spatial coordinates of the biological specimen in the mould; and
extracting one or more sample(s) of the biological specimen in the mould, based on the spatial coordinates of the at least one medical image of the biological specimen;
   thereby obtaining one or more samples of the biological specimen spatially correlated to the at least one medical image(s) of said biological specimen.

In some embodiments, the methods described herein may be performed on the biological specimen as described herein, for instance the biological specimen may be from a human or non-human animal. In some other embodiments, the biological specimen may be obtained from a plant, and may for example be a whole fruit or vegetable, or parts thereof.

The person skilled in the art will appreciate that biological specimens can be prepared according to different specific protocols depending on the medical imaging modality used. The method of preparation can be any method of preparation known in the art suitable for the medical imaging modality. The biological specimen may be a fresh biological specimen, for instance a fresh organ or tissue. The biological specimen may also be fixed. Fixation may be achieved for example by using precipitating or crosslinking compounds such as acids, alcohols, ketones, or aldehydes. For fixation formaldehyde may be employed (for example in the form of a 4-10 wt.-% aqueous solution, referred to as “formalin”). In some embodiments, the biological specimen is a fresh specimen or a fixed specimen.

In further embodiments, the biological specimen is formalin-fixed.

In preferred embodiments of the present invention, the biological specimen is a resected organ of parts thereof. In further embodiments, the resected organ is selected from the group consisting of: a brain, a kidney, a liver, a lung and a heart.

In some embodiments of the present invention, the biological specimen is obtained from a human or non-human animal subject suffering from a medical condition and/or having received a therapy or a surgical intervention prior to the step of providing the biological specimen. The medical condition may be for example selected from the group consisting of: cancer, such as brain cancer, ischemic diseases, such as stroke, and neurological diseases.

The therapy or surgical intervention may be, but not limited to, for instance a medical therapy, a training-based therapy, a neuromodulatory therapy, a pharmacological treatment, or a surgical intervention aimed at modelling a brain injury or brain ischemic event. The subject may be any animal or human, such as a mammal, such as but not limited to human, primate, livestock animal (e.g., sheep, cow, horse, donkey, pig), companion animal (e.g., dog, coat), laboratory test animal (e.g., mouse, rabbit, rat, guinea pig, hamster), captive wild animal (e.g., fox, deer).

The subject may preferably be an animal model of a disease, such as, but not limited to an animal model of a neurological disease, an oncogenic disease, a cardiovascular disease or a metabolic disease.

In some embodiments of the present invention, the biological specimen provided in the methods is a brain and the surgical procedure is selected from the group consisting of: deep brain stimulation (DBS) and focused ultrasound surgery (FUS).

The mould of the methods described herein may be held by the non-magnetic device as described further above.

In some embodiments, the biological specimen may be arranged, for instance embedded, within the mould, for example the mouldable non-ferromagnetic material, such as the alginate polymer described herein. The biological specimen may be covered or surrounded totally or partially by the mould. The biological specimen may be arranged in the mould in several steps, for instance the biological specimen may be placed in a first amount of moulding material allowing to orientate the biological specimen as desired, optionally allowing polymerization of the first amount of moulding material, followed by the addition and polymerization of the remainder of the moulding material in one or several steps.

In preferred embodiments, the mould is allowed to polymerize prior to the step of acquiring the medical image and/or the steps of extracting the one or more sample(s) of the biological specimen.

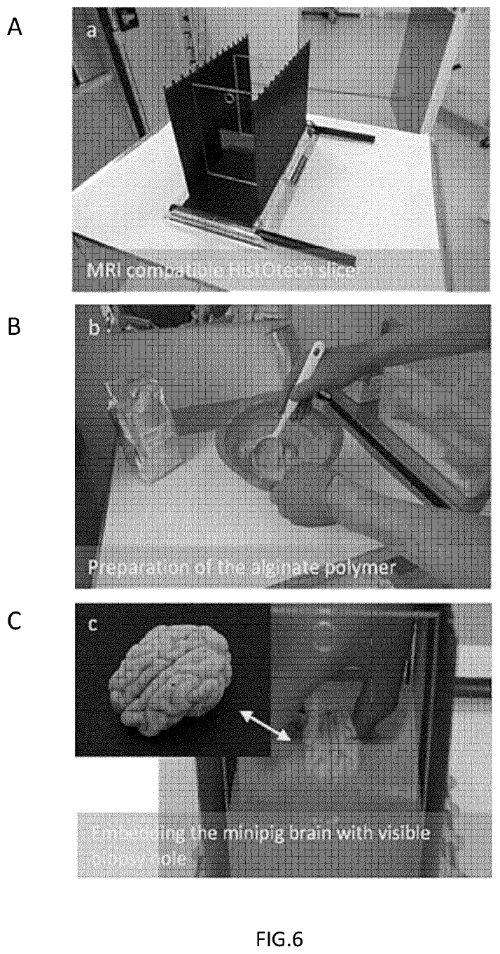

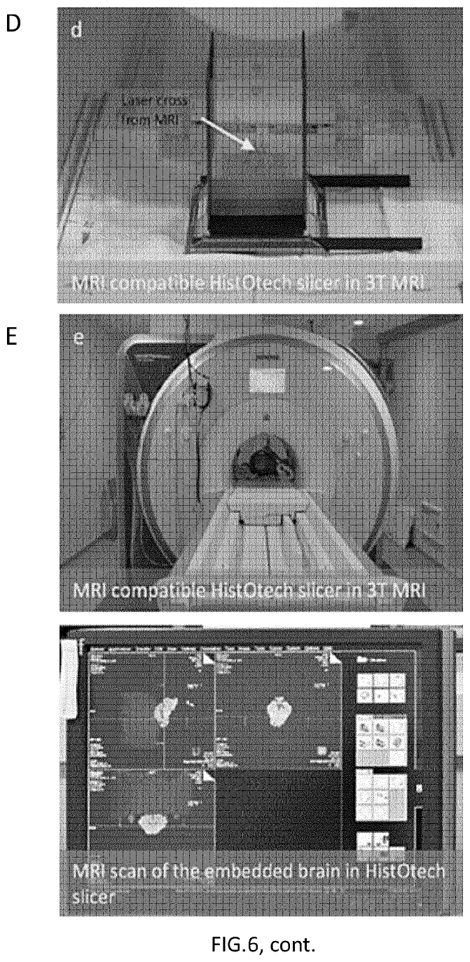

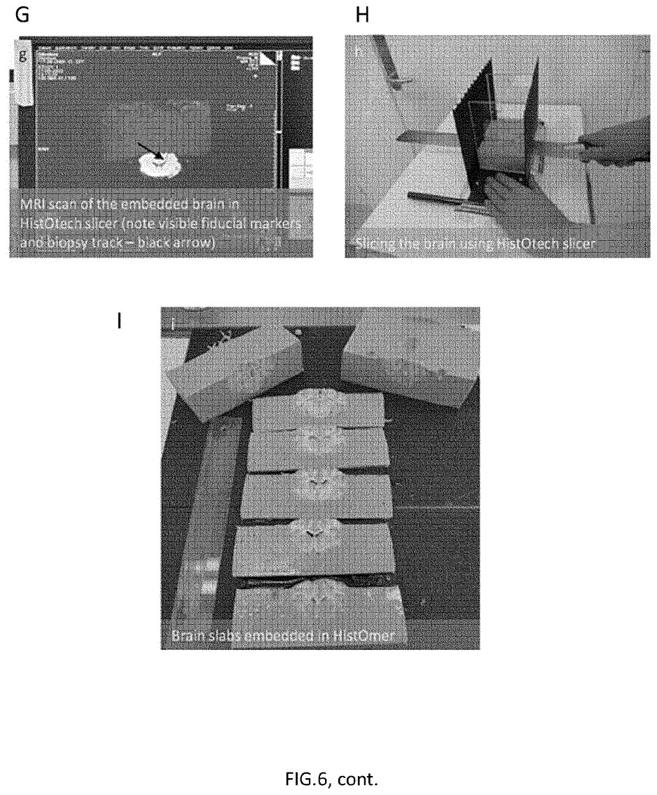

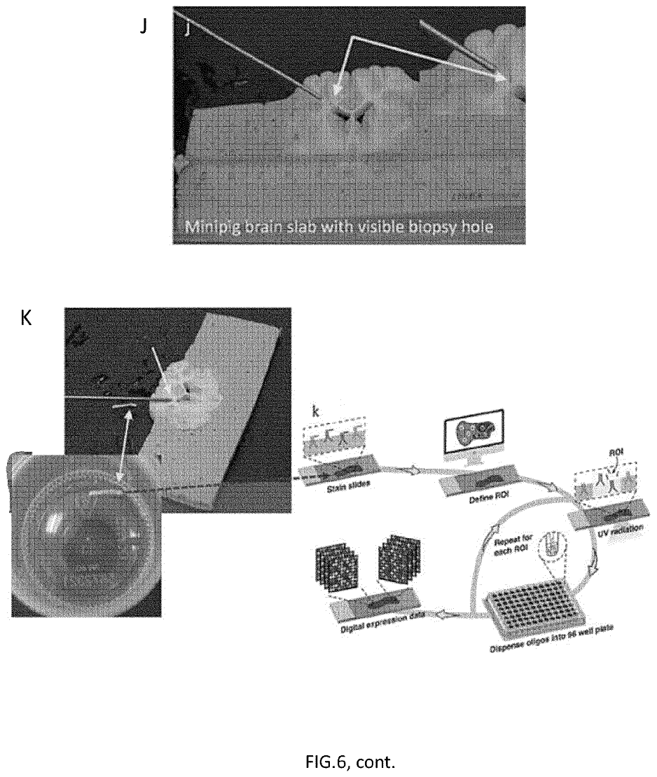

In some other embodiments, the biological specimen provided may optionally have been subjected to a step of extraction of one or more sample(s), such as a step of biopsy, prior to the step of acquiring at least one medical image of the biological specimen in the mould, said medical image(s) comprising a spatial reference. In such embodiments, the location of the one or more extracted sample(s) visible at the step of acquiring at least one medical image of the biological specimen in the mould may be used as the spatial reference (as shown for example in FIG. 6G-K). In such embodiments, the spatial reference may for instance be the observable cavity within the biological specimen after biopsy, or any other spatial reference observable by the medical imaging. In such embodiments, the one or more sample(s) extracted may also further be subjected to at least one histological, tissue imaging and/or spatial transcriptomic analysis.

The steps of arranging the biological specimen in a mould for holding the biological specimen to extracting one or more samples of the biological specimen in the mould of the methods as described herein may be performed using the kit as described herein. Preferably, the medical imaging of the biological specimen is magnetic resonance imaging.

For some applications it may be preferable that the step of acquiring at least one medical image does not exceed a certain duration, for example to prevent acquisition issues linked to the degradation of the biological sample, for example the dehydration of the biological sample in MRI scanning.

For the step of acquiring at least one medical image of the biological specimen in the mould, the biological specimen is preferably positioned for imaging in a 3D position wherein the imaging scanning plane is completely parallel to the surface according to which the extraction of the biological specimen, for example by slicing, will be performed. The biological specimen may thus be preferably positioned for imaging in a 3D position wherein the imaging scanning plane is completely parallel to the surface defined between two directly opposite rods on the supporting base 104 of the device described herein. The skilled person will appreciate that the positioning of the biological specimen can be performed for instance with the help of a positioning system used for medical imaging, such as a laser positioning system, for instance a laser positioning system based on laser crosshairs and/or a laser bridge. In such embodiments, the subsequent extraction by slicing can thus be performed according to the same plane as the imaging scanning plane, thereby enabling to correlate coordinates across the whole surface of the one or more slice(s) with the corresponding at least one medical image. The skilled person will also appreciate that in some other applications, for example for stereological analysis, the specimen may be placed randomly in the mould, for instance prior to or after random sampling on the specimen for analysis, such as cell count analysis or gene analysis.

The spatial reference of the medical image(s) can be obtained by any method known in the art compatible with the medical imaging used. The spatial reference can be based on coordinates, or a coordinate system, or direct or indirect distance measurement present on the medical images, for example manual or automated coordinates or coordinate system, or direct or indirect distance measurement, for example automatically provided by the medical imaging mean used, or by a measurement device fitted to it enabling to provide a spatial reference to the medical images. The spatial reference in the images(s) can also for instance be obtained using one or more fiducial markers or the fiducials as for instance described herein, such as the N-bar or N-localizer as described herein.

In some cases, the spatial reference can also be provided for example by a specific anatomical structure or anatomical anomaly, natural or provoked, recognizable by the person skilled in the art on the at least one medical image(s) and on the one or more sample(s) of the biological specimen. Examples of anatomical structures or anatomical anomalies include but not limited to: tumors, necrotic areas, vascular anomalies, haemorrhage areas, fractures, wounds. In such cases, the correlation between the spatial coordinates of the image(s) and spatial coordinates of the biological specimen in the mould may be performed for instance visually.

In another embodiment, the duration of the acquisition of at least one medical image is at most 72h, for instance at most 18 h, such as at most 24 h, for instance at most 12 h, such as at most 6h, for instance at most 3h, such as at most 2h, for instance at most 1h, such as at most 30 min.

The step of extracting one or more sample(s) of the biological specimen in the mould of the methods of the present invention may be performed by sectioning. The sectioning may be performed using a knife for sectioning the biological specimen into slices. The skilled person will appreciate that the structure of the one or more sample(s) of the biological specimen is preferably preserved during the slicing procedure.

The knife may be as described herein and may comprise a blade made in titanium, steel or carbon. The knife blade may have a thickness between 0.1 and 1 mm, preferably the knife blade may have a thickness between 0.1 and 0.9 mm. The blade length may preferably be between 10 cm and 50 cm, more preferably between 30 cm and 50 cm.

The step of correlating the spatial coordinates of the image(s) to spatial coordinates of the biological specimen in the mould may be performed by any mean known in the art, for instance directly or indirectly, for example with the help of fiducial markers as described herein and/or for example by distance measurements based on the spatial reference in the at least one medical image(s).

The step of extracting one or more sample(s) of the biological specimen in the mould is preferably performed so that the one or more sample(s) contain the x; y; z coordinates of the biological specimen imaged on the at least one medical image. In preferred embodiments, the one or more samples, such as the one or more slice(s) are of the minimum thickness allowable by the non-magnetic device and contain the x; y; z coordinates of the biological specimen imaged on the at least one medical image.

In some preferred embodiments, the non-magnetic device for holding the biological specimen may further comprise a stereotaxic unit defining the biological specimen in stereotaxic space.

### Image Guided Stereotaxic Sampling

Another aspect of the present invention thus relates to a method of image guided stereotaxic sampling of a biological specimen, comprising the steps of:
providing a biological specimen;
arranging the biological specimen in a mould;
acquiring at least one medical image of the biological specimen in the mould, said medical image(s) comprising a spatial reference;
obtaining spatial coordinates of the biological specimen in the image(s) based on the spatial reference;
correlating the spatial coordinates of the image(s) to spatial coordinates of the biological specimen in the mould; and
extracting one or more sample(s) of the biological specimen in the mould based on a stereotaxic space definition;
thereby obtaining one or more stereotaxically extracted sample(s) of the biological specimen and spatially correlated to the at least one medical image of said biological specimen.

The stereotaxic space definition can be performed by any mean of stereotaxic space definition known in the art. The mean of stereotaxic space definition can for instance comprise the stereotaxic frame systems described herein or be a frameless system. The mean of stereotaxic space definition can be combined with the biological specimen, for instance with the non-magnetic device holding the non-ferromagnetic mouldable material wherein the biological specimen is arranged prior to, during or after the step of acquiring at least one medical image of the biological specimen.

In some embodiments the mean of stereotaxic space definition is frameless or frame-based.

In some applications, it may be beneficial to be able to maintain the location information between for instance the medically imaged area of interest of the biological specimen and the sample(s) of the stereotaxically resolved biological specimen.

Thus, in another embodiment, the spatial coordinates of the one or more sample(s) of the biological specimen are correlated to the digital voxels of the MRI image(s).

The correlation of the spatial coordinates of the extracted one or more sample(s) to the spatial coordinates of the at least one medical image of the biological specimen may be performed for example by extracting one or more slice(s) of the biological specimen wherein the one or more slice(s) contain the x; y; z coordinates of the at least one medical image, such as the digital voxels of the MRI image(s). In preferred embodiments, the one or more slice(s) are of the minimum thickness allowable by the non-magnetic device and contain the x; y; z coordinates. The extraction localization can for example be measured relatively to fiducial markers embedded in the polymer in the device.

The correlation of the spatial coordinates of the extracted one or more sample(s) to the spatial coordinates of the at least one medical image of the biological specimen may be also performed for example by extracting one or more biopsy(ies) from the biological sample using the mean of stereotaxic space definition, wherein the one or more biopsy(ies) contain the x; y; z coordinates of the medical image. In such embodiments, one or more slice(s) of the biological specimen containing the x; y; z coordinates of the at least one medical image and/or or of the one or more biopsy(ies) can be further extracted, as shown in FIG. 6G-K.

The person skilled in the art will appreciate that for some applications, it may be required or beneficial to extract small regions of interest (ROI) of a biological specimen, for instance to focus on fine structures, while for other applications it may be required or beneficial to extract large regions representing the biological specimen to a greater extent, for instance when performing organ or tumor-wide screenings.

Thus in some embodiments, the size of the one or more sample(s) of the biological specimen correlated to digital voxels of the MRI image is at most 50 μm, such as at most 100 μm, for instance at most 200 μm, such as at most 400 μm, for instance at most 600 μm, such as at most 800 μm, for instance at most 1 mm, such as at most 1.5 mm, for instance at most 2 mm, such at most 2.5 mm, for instance at most 3 mm, such as at most 3.5 mm, for instance at most 4 mm, such as at most 4.5 mm, for instance at most 5 mm, such as at most 10 mm, for instance at most 20 mm, such as at most 30 mm for instance at most 40 mm, such as at most 50 mm, for instance at most 100 mm, such as at most 150 mm, for instance at most 200 mm, such as at most 250 mm for instance at most 300 mm.

The step of extracting one or more sample(s) of the biological specimen in the mould based on the spatial coordinates of the at least one medical image of the biological specimen and/or based on the stereotaxic space definition of the method of the present invention may also be performed by biopsy, surgical resection, autopsy or necropsy. For example, the method of the present invention may thus be applied, but not limited to, the fields of human or veterinary medical research, human or veterinary fundamental research, human or veterinary clinical research, human or veterinary drug development, human or veterinary legal and forensic medicine, or agricultural research and development, such as plant research and development, for example fruit crop and/or vegetable crop research and development. The method may preferably be applied to human or veterinary neuroscience.

In one preferred embodiment of the invention, the method further comprises a step of performing at least one histological, tissue imaging, spatial transcriptomics, biochemical, spectrometric, and/or chromatographic analysis on the one or more sample(s) of the biological specimen.

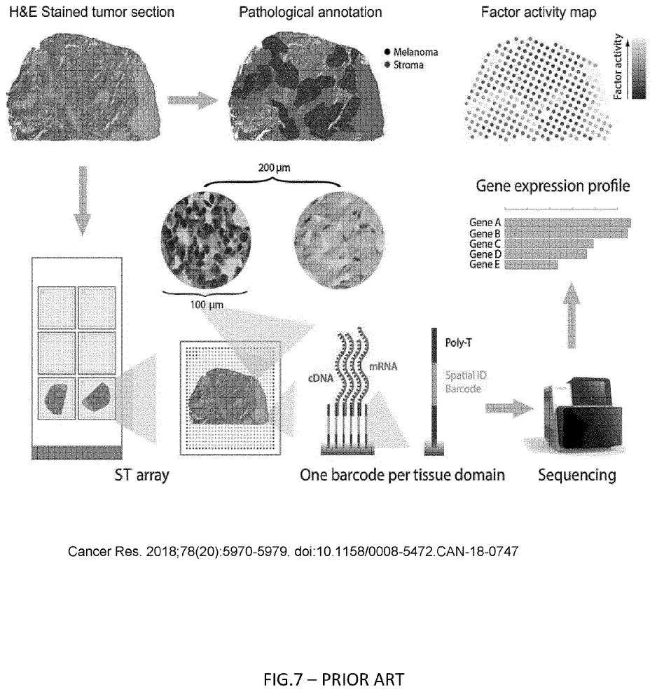

In another preferred embodiment of the invention, the method further comprises a step of combining the medical images of the one or more sample(s) of the biological specimen with the at least one histological, a tissue imaging, spatial transcriptomics, biochemical, spectrometric, and/or chromatographic analysis. The combination of the medical imaging of the one or more sample(s) of the stereotaxically resolved biological specimen with the at least one histological or spatial transcriptomic analysis can be performed for example by overlaying of the medical image with the data of the at least one histological, a tissue imaging, spatial transcriptomics, biochemical, spectrometric, and/or chromatographic analysis obtained for the corresponding location on the medical image. The spatial transcriptomics analysis workflow may be, but not limited to, as shown in FIG. 7, obtained from Thrane et al., Cancer Res. 2018; 78(20):5970-5979. doi: 10.1158/0008-5472.CAN-18-0747.

The present invention thus also relates to a method of combining the medical imaging of the one or more sample(s) of a biological specimen (animal, human or plant) with the data of at least one histological or spatial transcriptomic analysis, the method comprising the steps of:
providing a biological specimen;
arranging the biological specimen in a mould for holding the biological specimen;
acquiring at least one medical image of the biological specimen in the mould, said medical image(s) comprising a spatial reference;
obtaining spatial coordinates of the biological specimen in the image(s) based on the spatial reference;
correlating the spatial coordinates of the image(s) to spatial coordinates of the biological specimen in the mould;
extracting one or more sample(s) of the biological specimen in the mould;
performing at least one histological, a tissue imaging, spatial transcriptomics, biochemical, spectrometric, and/or chromatographic analysis on the one or more sample(s) of the biological specimen spatially correlated to the at least one medical image(s) of said biological specimen;
combining the at least one medical image(s) of said biological specimen with the data of the at least one histological or spatial transcriptomic analysis.

In preferred embodiments of the present invention, the method further comprises a step of sub-processing the one or more sample(s) of the biological specimen spatially correlated to the at least one medical image(s) of said biological specimen, or parts thereof, into one or more sub-sample(s).

In yet further embodiments, the method further comprises a step of correlating the spatial coordinates of the one or more sub-sample(s) to the spatial coordinates of the at least one medical image(s) of the biological specimen.

The present invention thus also relates to a method of sub-processing one or more sample(s) of a biological specimen, or parts thereof, into one or more sub-sample(s), wherein the location of the one or more sub-sample(s) can be correlated to their location of origin on the biological specimen, the method comprising the steps of:
providing a biological specimen;
arranging the biological specimen in a mouldable non-ferromagnetic material for holding the biological specimen;
acquiring at least one medical image of the biological specimen in the mould, said medical image(s) comprising a spatial reference;
obtaining spatial coordinates of the biological specimen in the image(s) based on the spatial reference;
correlating the spatial coordinates of the image(s) to spatial coordinates of the biological specimen in the mould;
extracting one or more sample(s) of the biological specimen in the mould;
sub-processing the one or more sample(s) of the biological specimen, or parts thereof, into one or more sub-sample(s); and
correlating the spatial coordinates of the one or more sub-sample(s) to the spatial coordinates of the at least one medical image(s) of the biological specimen.

In preferred embodiments, the one or more sample(s) of the biological specimen, or parts thereof is (are) frozen prior to or after the sub-processing. The one or more sub-sample(s) may also be frozen prior to or after the sub-processing.

The person skilled in the art will appreciate that the one or more sample(s) of the biological specimen or the one or more sub-sample(s) may be prepared with any suitable biological sample preparation known in the art, for example any histological sample preparation known in the art, such as any suitable preservation method, fixation method, embedding method, sectioning method and staining method. The one or more sample(s) or the one or more sub-sample(s) may for example be fresh-frozen or formalin-fixed paraffin-embedded (FFPE) for further analysis.

In preferred embodiments the step of sub-processing is selected from the group consisting of: tissue microdissection, cryosectioning, tissue dissociation and tissue lysis.

The step of sub-processing is preferably be performed in a manner that enables to retain the location information of the one or more sub-sample(s) to the one or more sample(s) of the stereotaxically resolved biological specimen. In preferred embodiments, the cryosectioning is a serial cryosectioning.

The methods descried herein may further comprise a step of analyzing the one or more sub-samples obtained by a histological, a tissue imaging and/or a spatial transcriptomics and/or biochemical and/or mass spectometric and/or chromatographic technique. The histological, tissue imaging and/or spatial transcriptomics and/or biochemical and/or mass spectometric and/or chromatographic technique may be any suitable histological, tissue imaging and/or spatial transcriptomics and/or biochemical and/or mass spectometric and/or chromatographic technique known in the art. For example, the spatial transcriptomics technique may be selected from the group consisting of: in-situ hybridization, such as fluorescent in-situ hybridization (FISH), spatial genomics analysis, spatial Multiomics Single-Cell Imaging analysis, RNA-seq, RNA assay, scRNA-seq, and in-situ sequencing. For example, the spatial genomics analysis may be GeoMX® as described in Merritt et al. 2020, Nature Biotechnology volume 38, pages 586-599 (2020), and the spatial Multiomics Single-Cell Imaging analysis may be CosMX™ as described in He et al. 2021, bioRxiv 2021.11.03.467020.

In preferred embodiments, the tissue imaging technique is selected from the group consisting of: light microscopy, fluorescence microscopy such as laser-scanning confocal microscopy, tissue scanning fluorescence microscopy. The transcriptomics analysis may be performed for instance, but not limited to, as presented on FIG. 7.

In further embodiments, the method further comprises a step of combining the at least one medical image(s) of the one or more sample(s) of the biological specimen from which the sub-samples were obtained, with the at least one histological, a tissue imaging, spatial transcriptomics, biochemical, spectrometric, and/or chromatographic analysis. The combination can be performed as described further above in the combination of the medical images of the one or more sample(s) of the biological specimen with the at least one histological, a tissue imaging, spatial transcriptomics, biochemical, spectrometric, and/or chromatographic analysis.

The present invention thus also relates to a method of sub-processing one or more sample(s) of a biological specimen, or parts thereof, into one or more sub-sample(s), wherein the location of the one or more sub-sample(s) can be correlated to their location of origin on the biological specimen, the method comprising the steps of:
providing a biological specimen;
arranging the biological specimen in a mouldable non-ferromagnetic material for holding the biological specimen;
acquiring at least one medical image of the biological specimen in the mould, said medical image(s) comprising a spatial reference;
obtaining spatial coordinates of the biological specimen in the image(s) based on the spatial reference;
correlating the spatial coordinates of the image(s) to spatial coordinates of the biological specimen in the mould;
extracting one or more sample(s) of the biological specimen in the mould; sub-processing the one or more sample(s) of the biological specimen, or parts thereof, into one or more sub-sample(s);
correlating the spatial coordinates of the one or more sub-sample(s) to the spatial coordinates of the at least one medical image(s) of the biological specimen;
analyzing the one or more sub-samples obtained by a histological, a tissue imaging and/or a spatial transcriptomics and/or biochemical and/or mass spectometric and/or chromatographic technique.
combining the at least one medical image(s) of the one or more sample(s) of the biological specimen from which the sub-samples were obtained, with the at least one histological, a tissue imaging, spatial transcriptomics, biochemical, spectrometric, and/or chromatographic analysis.

FIG. 7 shows an example of spatial transcriptomics approach, based on tumor sections. The figures disclose histology approaches, such as H&E staining, combined with spatial transcriptomics, reverse-transcription-based arrays, including spatial barcoding and downstream sequencing, allowing to combine histology, pathological annotation, and spatial gene expression profiles. Samples, and/or sub-samples of the biological specimen spatially correlated to the at least one medical image(s) of said biological specimen obtained by the methods of the present invention may be used for spatial transcriptomics approaches, thereby allowing to correlate the data obtained by spatial transcriptomics approaches, to the spatial coordinates of the sample or sub-sample(s) and to the spatial coordinates of the at least one medical image(s).

### FURTHER DETAILS

1. A device for holding a biological specimen during medical imaging, said device comprising a non-magnetic medical imaging compatible reference frame, wherein the device is configured for sustaining the biological specimen in fixed relation to the non-magnetic medical imaging compatible reference frame, such that at least one sample can be acquired from the biological specimen in fixed spatial relation with the non-magnetic medical imaging compatible reference frame after medical imaging.
2. The device according to item 1, wherein the non-magnetic medical imaging compatible reference frame comprises a non-magnetic supporting base and at least two rows of non-magnetic elements, and wherein the device is configured for sustaining the biological specimen on the non-magnetic supporting base between the at least two rows of non-magnetic elements such that the biological specimen can be sliced along the non-magnetic elements into slices of a predetermined thickness and orientation after medical imaging.
3. The device according to item 1, wherein the fixed spatial relation is defined by an original placement of the biological specimen within the non-magnetic medical imaging compatible reference frame.
4. The device according to item 3, wherein the original placement is defined by an orientation and a position of the biological specimen within the non-magnetic medical imaging compatible reference frame.
5. The device according to any one of the preceding items, wherein the medical imaging is magnetic resonance imaging.
6. The device according to any one of the preceding items, wherein the non-magnetic supporting base has a surface, wherein the surface is extendable and/or retractable.
7. The device according to item 6, wherein the surface is plane.
8. The device according to item 6, wherein the surface has an area between 5 cm² and 1000 cm².
9. The device according to any one of the preceding items, wherein the non-magnetic elements are separated with a spacing distance.
10. The device according to item 9, wherein the spacing distance defines the predetermined thickness.
11. The device according to item 9, wherein the spacing distance is between 0.2 mm and 4 mm, preferably between 0.4 mm and 2 mm, even more preferably 1 mm.
12. The device according to any one of the preceding items, wherein the at least two rows of non-magnetic elements are arranged at a plurality of boundaries of the non-magnetic supporting base.
13. The device according to any one of the preceding items, wherein the non-magnetic elements are arranged such as at least one non-magnetic element is visually different than the others.
14. The device according to any one of the preceding items, wherein the non-magnetic elements have either a primary or a secondary length, wherein the primary length is different from the secondary length.
15. The device according to item 14, wherein the non-magnetic elements having the primary length are arranged between every two non-magnetic elements and ten non-magnetic elements in each one of the at least two rows of non-magnetic elements, preferably between every five non-magnetic elements.
16. The device according to item 14, wherein the primary length is between 10 and 400 mm, preferably between 20 and 200 mm.
17. The device according to item 14, wherein the secondary length is between 1% and 10% lower or higher than the primary length, preferably between 4% and 6% lower or higher than the primary length.
18. The device according to any one of the preceding items, wherein the non-magnetic elements are non-magnetic rods, non-magnetic plates, non-magnetic lamellae or non-magnetic slats.
19. The device according to item 18, wherein the non-magnetic rods are cylinders.
20. The device according to item 19, wherein the cylinders are right circular cylinders.
21. The device according to item 20, wherein the right circular cylinders comprise a primary axis defined by crossing two centres of two ends of the cylinders.
22. The device according to item 21, wherein the right circular cylinders have a diameter between 1 mm and 1 cm, preferably between 2 mm and 5 mm, even more preferably 4 mm.
23. The device according to any one of the preceding items, wherein the primary axis of the right circular cylinders are perpendicular to the flat surface of the non-magnetic supporting base.
24. The device according to any one of the preceding items, wherein the at least two rows of non-magnetic rods are straight.
25. The device according to any one of the preceding items, wherein the at least two rows of non-magnetic rods are parallel.
26. The device according to any one of the preceding items, wherein the non-magnetic rods are made with carbon.
27. The device according to any one of the preceding items, wherein the biological specimen is a block of tissue.
28. The device according to item 27, wherein the block of tissue is an organ.
29. The device according to any one of the preceding items, further comprising a stereotaxic unit configured for being arranged in fixed spatial relation to the non-magnetic medical imaging compatible reference frame for defining the biological specimen in stereotaxic space during medical imaging.
30. The device according to item 29, wherein the stereotaxic unit is configured for detachable attachment on the non-magnetic medical imaging compatible reference frame such that a stereotaxic space correlation between medical imaging and slices of the biological specimen can be obtained.
31. The device according to item 29, wherein the stereotaxic unit is arranged on the non-magnetic medical imaging compatible reference frame.
32. The device according to item 29, wherein the stereotaxic unit is compatible with medical resonance imaging.
33. The device according to any one of the preceding items, wherein the stereotaxic unit comprises a localization device.
34. The device according to any one of the preceding items, wherein the stereotaxic unit is a stereotaxic localizer box.
35. The device according to item 33, wherein the localization device is a N-localizer.
36. The device according to item 33, wherein the localization device is at least one fiducial marker.
37. The device according to item 29, wherein the stereotaxic unit is a stereotaxic frame system.
38. The device according to item 37, wherein the stereotaxic frame system is selected from the group arc-quadrant system, simple orthogonal system, Burr hole mounted system, and arc-phantom system.
39. The device according to any of the preceding items, wherein the stereotaxic unit comprises a sample collector unit configured for acquiring at least one secondary sample of the biological specimen.
40. The device according to any of the preceding items, wherein the sample collector unit is movable along an arc defined by the stereotaxic unit.
41. The device according to any of the preceding items, wherein the sample collector unit is configured for performing an incisional biopsy or core biopsy.
42. The device according to item 39, wherein the sample collector unit comprises a biopsy tool.
43. The device according to item 42, wherein the biopsy tool is selected from a group of: needle, biopsy needle, hollow needle, scalpels, scissors, forceps, curette, punch.
44. The device according to any one of the preceding items, wherein the sample collector unit is configured for acquiring the at least one secondary sample of the biological specimen is arranged on the stereotaxic frame system.
45. The device according to item 39, wherein the at least one secondary sample is comprised within the biological specimen.
46. The device according to any of the preceding items, wherein the at least one secondary sample is substantially smaller than the at least one sample.
47. The device according to any of the preceding items, wherein the at least one secondary sample is a biopsy specimen, biopsy sample or a voxel of the biological specimen.
48. The device according to any one of the preceding items, wherein the device comprises a plurality of movable walls.
49. The device according to item 48, wherein each one of the plurality of movable walls are vertically arranged at a plurality of outer boundaries of the device.
50. The device according to any one of the preceding items, wherein the plurality of movable walls are made of plastic.
51. The device according to any one of the preceding items, wherein the non-magnetic supporting base is made of plastic.
52. A kit for holding and/or sectioning a biological specimen comprising:
   a device for holding a biological specimen during medical imaging according to any of items 1-51;
   a knife for sectioning the biological specimen into slices; and/or
   a mouldable non-ferromagnetic material for arranging the biological specimen in the device.
53. The kit according to item 52, wherein the knife comprises a blade made in titanium, steel or carbon.
54. The kit according to item 53, wherein the blade has a thickness between 0.1 and 1 mm, preferably between 0.1 and 0.9 mm.
55. The kit according to any one of items 52-54, wherein the blade has a length between 10 and 50 cm, preferably between 30 and 50 cm.
56. The kit according to item 52, wherein the mouldable non-ferromagnetic material is removed without damaging the biological specimen.
57. The kit according to item 56, wherein the mouldable non-ferromagnetic material is an alginate embedding material.
58. The kit according to item 57, wherein the alginate embedding material polymerizes in one to ten minutes, preferably in two to five minutes.
59. A method of correlating medical imaging and sampling of a biological specimen, comprising the steps of:
   providing a biological specimen;
   arranging the biological specimen in a mould for holding the biological specimen;
   acquiring at least one medical image of the biological specimen in the mould, said medical image(s) comprising a spatial reference;
   obtaining spatial coordinates of the biological specimen in the medical image(s) based on the spatial reference;
   correlating the spatial coordinates of the medical image(s) to spatial coordinates of the biological specimen in the mould; and
   extracting one or more samples of the biological specimen in the mould;
   thereby obtaining one or more sample(s) of the biological specimen spatially correlated to the at least one medical image of said biological specimen.
60. The method according to item 59, wherein the biological specimen is from a human or non-human animal.
61. The method according to item 59, wherein the biological specimen is from a plant, such as a whole fruit or vegetable, or parts thereof.
62. The method according to any one of items 59 to 61, wherein the biological specimen is a fresh specimen or a fixed specimen.
63. The method according to item 62, wherein the biological specimen is formalin-fixed.
64. The method according to any one of items 59 to 63, wherein the biological specimen is a resected organ or parts thereof.
65. The method according to item 64 wherein the resected organ is selected from the group consisting of: a brain, a kidney, a liver, a lung and a heart.
66. The method according to any one of items 59 to 60, 62 to 65 wherein the biological specimen is obtained from a human or non-human animal subject suffering from a medical condition and/or a human or non-human animal subject having received a therapy or surgical intervention prior to the step of providing the biological specimen.
67. The method according to item 66 wherein the medical condition is selected from the group consisting of: cancer, such as brain cancer, ischemic diseases, such as stroke, and neurological diseases.
68. The method according to any one of items 66 to 67, wherein the biological specimen is a brain and the surgical procedure is selected from the group consisting of: deep brain stimulation (DBS) and focused ultrasound surgery (FUS).
69. The method according to any one of items 59 to 68, wherein the mould of the step of arranging the biological specimen in a mould for holding the biological specimen is held by the non-magnetic device according to any one of items 1 to 38.
70. The method according to any one of items 59 to 69, wherein the mould is a mouldable non-ferromagnetic material.
71. The method according to any one of items 59 to 70, wherein the steps of:
   arranging the biological specimen in a mould for holding the biological specimen;
   acquiring at least one medical image of the biological specimen in the mould, said medical image(s) comprising a spatial reference;
   obtaining spatial coordinates of the biological specimen in the medical image(s) based on the spatial reference;
   correlating the spatial coordinates of the medical image(s) to spatial coordinates of the biological specimen in the mould; and
   extracting one or more samples of the biological specimen in the mould;
   are performed using the kit according to any one of items 52 to 58.
72. The method according to any one of items 59 to 71, wherein the medical imaging of the biological specimen is magnetic resonance imaging.
73. The method according to any one of items 59 to 72, wherein the duration of the acquisition of the at least one medical image is at most 72h, for instance at most 18 h, such as at most 24 h, for instance at most 12 h, such as at most 6h, for instance at most 3h, such as at most 2h, for instance at most 1h, such as at most 30 min.
74. The method according to any one of items 59 to 73, wherein the step of extracting one or more samples of the biological specimen in the mould is performed by sectioning.
75. The method according to item 74, wherein the sectioning is performed using a knife for sectioning the biological specimen into slices.
76. The method according to item 75, wherein the knife comprises a blade made in titanium, steel or carbon.
77. The method according to item 76, wherein the blade has a thickness between 0.1 and 1 mm, preferably between 0.1 and 0.9 mm.
78. The method according to any one of items 74 to 77, wherein the blade has a length between 10 cm and 50 cm, preferably between 30 cm and 50 cm.
79. The method according to any one of items 59 to 72, wherein the mould for holding the biological specimen according to any one of items 59 to 78 or the non-magnetic device according to any one of items 69 to 78 further comprises a stereotaxic unit defining the biological specimen in stereotaxic space.
80. The method according to item 79, wherein the stereotaxic unit is frame-based or frameless.
81. The method according to any one of items 59 to 80, wherein the medical imaging is MRI, and wherein the spatial coordinates of the one or more sample(s) of the biological specimen are correlated to the digital voxels of the MRI image(s).
82. The method according to item 81, wherein the size of the one or more sample(s) of the biological specimen correlated to digital voxels of the MRI image is at most 50 μm, such as at most 100 μm, for instance at most 200 μm, such as at most 400 μm, for instance at most 600 μm, such as at most 800 μm, for instance at most 1 mm, such as at most 1.5 mm, for instance at most 2 mm, such at most 2.5 mm, for instance at most 3 mm, such as at most 3.5 mm, for instance at most 4 mm, such as at most 4.5 mm, for instance at most 5 mm, such as at most 10 mm, for instance at most 20 mm, such as at most 30 mm for instance at most 40 mm, such as at most 50 mm, for instance at most 100 mm, such as at most 150 mm, for instance at most 200 mm, such as at most 250 mm, for instance at most 300 mm.
83. The method according to any one of items 59 to 82, wherein the extraction of the one or more sample(s) of the biological specimen is performed by biopsy, surgical resection, autopsy or necropsy.
84. The method according to any one of items 59 to 83, further comprising a step of performing at least one histological tissue imaging, spatial transcriptomics, biochemical, spectrometric, chromatographic analysis on the one or more sample(s) of the biological specimen.
85. The method according to item 84, further comprising a step of combining the medical image(s) of the one or more sample(s) of the biological specimen with the at least one histological tissue imaging, spatial transcriptomics, biochemical, spectrometric, and/or chromatographic analysis.
86. The method according to any one of items 59 to 85, further comprising a step of sub-processing the one or more sample(s) of the biological specimen spatially correlated to the at least one medical image(s) of said biological specimen, or parts thereof, into one or more sub-sample(s).
87. The method according to item 86, further comprising a step of correlating the spatial coordinates of the one or more sub-sample(s) to the spatial coordinates of the at least one medical image(s) of the biological specimen.
88. The method according to item 87, wherein the one or more sample(s) of the biological specimen, or parts thereof is (are) frozen prior to or after the sub-processing.
89. The method according to any one of items 86 to 88, wherein the one or more sub-sample(s) is (are) frozen prior to or after the sub-processing.
90. The method according to any one of items 86 to 89, wherein the step of sub-processing is selected from the group consisting of: tissue microdissection, cryosectioning, tissue dissociation and tissue lysis.
91. The method according to item 90, wherein the cryosectioning is a serial cryosectioning.
92. The method according to any one of items 86 to 91, further comprising a step of analyzing the one or more sub-samples obtained by at least one histological, tissue imaging, spatial transcriptomics, biochemical, spectrometric, and/or chromatographic technique.
93. The method according to item 92, wherein the spatial transcriptomics technique is selected from the group consisting of: in-situ hybridization, such as fluorescent in-situ hybridization (FISH), spatial genomics analysis, spatial Multiomics Single-Cell Imaging analysis, RNA-seq, RNA assay, scRNA-seq, and in-situ sequencing.
94. The method according to any one of items 92 to 93, wherein the tissue imaging technique is selected from the group consisting of: light microscopy, fluorescence microscopy such as laser-scanning confocal microscopy, tissue scanning fluorescence microscopy.
95. The method according to any one of items 86 to 94, further comprising a step of combining the at least one medical image(s) of the one or more sample(s) of the biological specimen from which the sub-samples were obtained, with the at least one histological, tissue imaging, spatial transcriptomics, biochemical, spectrometric, and/or chromatographic analysis.

1. A device for holding a biological specimen during medical imaging, said device comprising a non-magnetic medical imaging compatible reference frame, wherein the device is configured for sustaining the biological specimen in fixed relation to the non-magnetic medical imaging compatible reference frame, such that at least one sample can be acquired from the biological specimen in fixed spatial relation with the non-magnetic medical imaging compatible reference frame after medical imaging, wherein the device further comprises a stereotaxic unit configured for being arranged in fixed spatial relation to the non-magnetic medical imaging compatible reference frame for defining the biological specimen in stereotaxic space during medical imaging, and wherein the stereotaxic unit is further configured for detachable attachment on the non-magnetic medical imaging compatible reference frame such that a stereotaxic space correlation between medical imaging and slices of the biological specimen can be obtained, wherein the stereotaxic unit comprises:
a stereotaxic frame system comprising a sample collector unit configured to perform an incisional biopsy or core biopsy of the biological specimen; and/or
a localization device, wherein the localization device is a N-localizer.

2. The device according to claim 1, wherein the non-magnetic medical imaging compatible reference frame comprises a non-magnetic supporting base and at least two rows of non-magnetic elements, and wherein the device is configured for sustaining the biological specimen on the non-magnetic supporting base between the at least two rows of non-magnetic elements such that the biological specimen can be sliced along the non-magnetic elements into slices of a predetermined thickness and orientation after medical imaging.

3. The device according to claim 1, wherein the sample collector unit is movable along an arc defined by the stereotaxic frame system.

4. The device according to claim 1, wherein the sample collector unit is configured for acquiring at least one secondary sample of the biological specimen, wherein the at least one secondary sample is a biopsy specimen, biopsy sample or a voxel of the biological specimen.

5. (canceled)

6. The device according to claim 1, wherein the sample collector unit comprises a biopsy tool, wherein the biopsy tool is selected from a group of: needle, biopsy needle, hollow needle, scalpels, scissors, forceps, curette, punch.

7. (canceled)

8. The device according to claim 1, wherein the medical imaging is magnetic resonance imaging.

9. A kit for holding and/or sectioning a biological specimen comprising:
a device for holding a biological specimen during medical imaging according to claim 1;
a knife for sectioning the biological specimen into slices; and/or
a mouldable non-ferromagnetic material for arranging the biological specimen in the device.

10. The kit according to claim 9, wherein the mouldable non-ferromagnetic material is an alginate embedding material or an alginate derived embedding material.

11. The kit according to claim 9, wherein the mouldable non-ferromagnetic material is compatible with magnetic resonance imaging.

12. The kit according to claim 9, wherein the mouldable non-ferromagnetic material is configured to result in a low intensity magnetic resonance image with no visible distortion or noise and/or to deliver a null MRI signal.

13. The kit according to claim 9, comprising a cavity tool configured to create a cavity in a selected part of the non-ferromagnetic material, such that said cavity forms a fiducial marker in magnetic resonance imaging, wherein the cavity tool is arranged on the stereotaxic frame system.

14. (canceled)

15. A method of correlating medical imaging and sampling of a biological specimen to perform at least one histological tissue analysis, comprising the steps of:
providing a biological specimen;
arranging the biological specimen in a mould for holding the biological specimen;
acquiring at least one medical image of the biological specimen in the mould, said medical image(s) comprising a spatial reference;
obtaining spatial coordinates of the biological specimen in the medical image(s) based on the spatial reference;
correlating the spatial coordinates of the medical image(s) to spatial coordinates of the biological specimen in the mould; and
extracting one or more samples of the biological specimen in the mould, thereby obtaining one or more sample(s) of the biological specimen spatially correlated to the at least one medical image of said biological specimen;
performing at least one histological tissue analysis selected from the group of: histological tissue imaging, spatial transcriptomics, biochemical, spectrometric, chromatographic analysis on the one or more sample(s) of the biological specimen; and
combining the medical image(s) of the one or more sample(s) of the biological specimen with the at least one histological tissue imaging, spatial transcriptomics, biochemical, spectrometric, and/or chromatographic analysis.

16. The method according to claim 15, wherein the mould of the step of arranging the biological specimen in a mould for holding the biological specimen is held by a non-magnetic device, wherein the non-magnetic device comprises a non-magnetic medical imaging compatible reference frame, wherein the non-magnetic device is configured for sustaining the biological specimen in fixed relation to the non-magnetic medical imaging compatible reference frame, such that at least one sample can be acquired from the biological specimen in fixed spatial relation with the non-magnetic medical imaging compatible reference frame after medical imaging, wherein the non-magnetic device further comprises a stereotaxic unit configured for being arranged in fixed spatial relation to the non-magnetic medical imaging compatible reference frame for defining the biological specimen in stereotaxic space during medical imaging, and wherein the stereotaxic unit is further configured for detachable attachment on the non-magnetic medical imaging compatible reference frame such that a stereotaxic space correlation between medical imaging and slices of the biological specimen can be obtained, wherein the stereotaxic unit comprises:
a stereotaxic frame system comprising a sample collector unit configured to perform an incisional biopsy or core biopsy of the biological specimen; and/or
a localization device, wherein the localization device is a N-localizer.

17. The method according to claim 15, wherein the mould is a mouldable non-ferromagnetic material.

18. The method according to claim 15, wherein the steps of:
arranging the biological specimen in a mould for holding the biological specimen;
acquiring at least one medical image of the biological specimen in the mould, said medical image(s) comprising a spatial reference;
obtaining spatial coordinates of the biological specimen in the medical image(s) based on the spatial reference;
correlating the spatial coordinates of the medical image(s) to spatial coordinates of the biological specimen in the mould; and
extracting one or more samples of the biological specimen in the mould;
are performed using a kit for holding and/or sectioning a biological specimen comprising:
a device for holding a biological specimen during medical imaging, wherein the device comprising a non-magnetic medical imaging compatible reference frame, wherein the device is configured for sustaining the biological specimen in fixed relation to the non-magnetic medical imaging compatible reference frame, such that at least one sample can be acquired from the biological specimen in fixed spatial relation with the non-magnetic medical imaging compatible reference frame after medical imaging, wherein the device further comprises a stereotaxic unit configured for being arranged in fixed spatial relation to the non-magnetic medical imaging compatible reference frame for defining the biological specimen in stereotaxic space during medical imaging, and wherein the stereotaxic unit is further configured for detachable attachment on the non-magnetic medical imaging compatible reference frame such that a stereotaxic space correlation between medical imaging and slices of the biological specimen can be obtained, wherein the stereotaxic unit comprises:
a stereotaxic frame system comprising a sample collector unit configured to perform an incisional biopsy or core biopsy of the biological specimen; and/or
a localization device, wherein the localization device is a N-localizer;
a knife for sectioning the biological specimen into slices; and/or
a mouldable non-ferromagnetic material for arranging the biological specimen in the device.

19. The method according to claim 15, wherein a mould for holding the biological specimen or a non-magnetic device further comprises a stereotaxic unit defining the biological specimen in stereotaxic space.

20. The method according to claim 15, wherein the medical imaging is MRI, and wherein the spatial coordinates of the one or more sample(s) of the biological specimen are correlated to the digital voxels of the MRI image(s).

21. The method according to claim 15, further comprising a step of sub-processing the one or more sample(s) of the biological specimen spatially correlated to the at least one medical image(s) of said biological specimen, or parts thereof, into one or more sub-sample(s) and a step of correlating the spatial coordinates of the one or more sub-sample(s) to the spatial coordinates of the at least one medical image(s) of the biological specimen.

22. The method according to claim 15, further comprising a step of analyzing the one or more sub-samples obtained by at least one histological, tissue imaging, spatial transcriptomics, biochemical, spectrometric, and/or chromatographic technique and a step of combining the at least one medical image(s) of the one or more sample(s) of the biological specimen from which the sub-samples were obtained, with the a least one histological, tissue imaging, spatial transcriptomics, biochemical, spectrometric, and/or chromatographic analysis.

23. The method according to claim 15, wherein the one or more samples are at least one secondary sample, and wherein the at least one secondary sample is a biopsy specimen, biopsy sample or a voxel of the biological specimen.
